(19) United States
(12) Patent Application Publication
(10) Pub. No.: US 2005/0189322 A1
(43) Pub. Date: Sep. 1, 2005

(54) Compositions and methods for chemical mechanical polishing silica and silicon nitride

(76) Inventors: Sarah J. Lane, Elkton, MD (US); Brian L. Mueller, Middletown, DE (US); Charles Yu, Wilmington, DE (US)

Correspondence Address: Rohm and Haas;Electronic Materials CMP Holdings, Inc., Suite 1300, 1105 North Market Street, Wilmington, DE, 19899, US

(21) Appl. No.: 10/788,654

(22) Filed: Feb. 27, 2004

(51) Int. Cl. B24D 3/02; C09K 13/00; B44C 1/22; H01L 21/76

(52) U.S. Cl. 216/88; 51/298; 51/307; 51/309; 252/79.1; 252/79.4; 216/89

(57) ABSTRACT

The present invention provides an aqueous composition useful for polishing silica and silicon nitride on a semiconductor wafer comprising by weight percent 0.01 to 5 zwitterionic compound, 0.01 to 5 carboxylic acid polymer, 0.02 to 6 abrasive, 0 to 5 cationic compound and balance water, wherein the zwitterionic compound has the following structure: 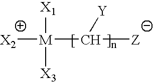
in which n is an integer, Y comprises hydrogen or an alkyl group, Z comprises carboxyl, sulfate or oxygen, M comprises nitrogen, phosphorus or a sulfur atom, and X₁, X₂ and X₃ independently comprise substituents selected from the group comprising, hydrogen, an alkyl group and an aryl group.

### BACKGROUND OF THE INVENTION

The invention relates to chemical mechanical planarization (CMP) of semiconductor wafer materials and, more particularly, to CMP compositions and methods for polishing silica and silicon nitride from semiconductor wafers in shallow trench isolation (STI) processes.

Decreasing dimensions of devices and the increasing density of integration in microelectronic circuits have required a corresponding reduction in the size of isolation structures. This reduction places a premium on reproducible formation of structures that provide effective isolation, while occupying a minimum amount of the substrate surface.

The STI technique is a widely used semiconductor fabrication method for forming isolation structures to electrically isolate the various active components formed in integrated circuits. One major advantage of using the STI technique over the conventional LOCOS (Local Oxidation of Silicon) technique is the high scalability to CMOS (Complementary Metal-Oxide Semiconductor) IC devices for fabrication at the submicron level of integration. Another advantage is that the STI technique helps prevent the occurrence of the so-called bird's beak encroachment, which is characteristic to the LOCOS technique for forming isolation structures.

In the STI technique, the first step is the formation of a plurality of trenches at predefined locations in the substrate, usually by anisotropic etching. Next, silica is deposited into each of these trenches. The silica is then polished by CMP, down to the silicon nitride (stop layer) to form the STI structure. To achieve efficient polishing, the polishing slurry must provide a high selectivity involving the removal rate of silica relative to silicon nitride (“selectivity”).

Kido et al., in U.S. Patent App. Pub. No. 2002/0045350, discloses a known abrasive composition for polishing a semiconductor device comprising a cerium oxide and a water soluble organic compound. Optionally, the composition may contain a viscosity adjusting agent, a buffer, a surface active agent and a chelating agent, although, none are specified. Although, the composition of Kido provides adequate selectivity, the ever-increasing density of integration in microelectronic circuits demand improved compositions and methods.

Hence, what is needed is a composition and method for chemical-mechanical polishing of silica and silicon nitride for shallow trench isolation processes having improved selectivity.

### STATEMENT OF THE INVENTION

In a first aspect, the present invention provides an aqueous composition useful for polishing silica and silicon nitride on a semiconductor wafer comprising by weight percent 0.01 to 5 zwitterionic compound, 0.01 to 5 carboxylic acid polymer, 0.02 to 6 abrasive, 0 to 5 cationic compound and balance water, wherein the zwitterionic compound has the following structure: 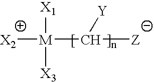
in which n is an integer, Y comprises hydrogen or an alkyl group, Z comprises carboxyl, sulfate or oxygen, M comprises nitrogen, phosphorus or a sulfur atom, and X₁, X₂ and X₃ independently comprise substituents selected from the group comprising, hydrogen, an alkyl group and an aryl group.

In a second aspect, the present invention provides an aqueous composition useful for polishing silica and silicon nitride on a semiconductor wafer comprising by weight percent 0.01 to 5 N,N,N-trimethylammonioacetate, 0.01 to 5 polyacrylic acid polymer, 0.02 to 6 ceria, 0 to 5 cationic compound and balance water, wherein the aqueous composition has a pH of 4 to 9.

In a third aspect, the present invention provides a method for polishing silica and silicon nitride on a semiconductor wafer comprising: contacting the silica and silicon nitride on the wafer with a polishing composition, the polishing composition comprising by weight percent 0.01 to 5 zwitterionic compound, 0.01 to 5 carboxylic acid polymer, 0.02 to 6 abrasive, 0 to 5 cationic compound and balance water; polishing the silica and silicon nitride with a polishing pad; and wherein the zwitterionic compound has the following structure: 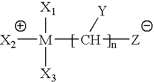
in which n is an integer, Y comprises hydrogen or an alkyl group, Z comprises carboxyl, sulfate or oxygen, M comprises nitrogen, phosphorus or a sulfur atom, and X₁, X₂ and X₃ independently comprise substituents selected from the group comprising, hydrogen, an alkyl group and an aryl group.

### DETAILED DESCRIPTION OF THE INVENTION

The composition and method provide unexpected selectivity for removing silica relative to silicon nitride. The composition advantageously relies upon a chelating agent or a selectivity enhancer to selectively polish silica relative to silicon nitride for shallow trench isolation processes. In particular, the composition comprises a zwitterionic compound to selectively polish silica relative to silicon nitride, at the pH of the application.

As defined herein, the term “alkyl” (or alkyl- or alk-) refers to a substituted or unsubstituted, straight, branched or cyclic hydrocarbon chain that preferably contains from 1 to 20 carbon atoms. Alkyl groups include, for example, methyl, ethyl, propyl, isopropyl, cyclopropyl, butyl, iso-butyl, tert-butyl, sec-butyl, cyclobutyl, pentyl, cyclopentyl, hexyl and cyclohexyl.

The term “aryl” refers to any substituted or unsubstituted aromatic carbocyclic group that preferably contains from 6 to 20 carbon atoms. An aryl group can be monocyclic or polycyclic. Aryl groups include, for example, phenyl, naphthyl, biphenyl, benzyl, tolyl, xylyl, phenylethyl, benzoate, alkylbenzoate, aniline, and N-alkylanilino.

The term “zwitterionic compound” means a compound containing cationic and anionic substituents in equal proportions joined by a physical bridge, for example, a CH₂ group, so that the compound is net neutral overall. The zwitterionic compounds of the present invention include the following structure: 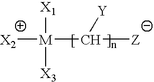
wherein n is an integer, Y comprises hydrogen or an alkyl group, Z comprises carboxyl, sulfate or oxygen, M comprises nitrogen, phosphorus or a sulfur atom, and X₁, X₂ and X₃ independently comprise substituents selected from the group comprising, hydrogen, an alkyl group and an aryl group.

Preferred zwitterionic compounds include, for example, betaines. A preferred betaine of the present invention is N,N,N-trimethylammonioacetate, represented by the following structure:

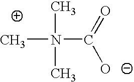

The composition advantageously contains 0.01 to 5 weight percent zwitterionic compound to selectively remove the silica relative to the silicon nitride. Advantageously, the composition contains 0.05 to 1.5 weight percent zwitterionic compound. The zwitterionic compound of the present invention may advantageously promote planarization and may suppress nitride removal.

In addition to the zwitterionic compound, the composition advantageously contains 0.01 to 5 weight percent of a carboxylic acid polymer. Preferably, the composition contains 0.05 to 1.5 weight percent of a carboxylic acid polymer. Also, the polymer preferably has a number average molecular weight of 4,000 to 1,500,000. In addition, blends of higher and lower number average molecular weight carboxylic acid polymers can be used. These carboxylic acid polymers generally are in solution but may be in an aqueous dispersion. The carboxylic acid polymer may advantageously serve as a dispersant for the abrasive particles (discussed below). The number average molecular weight of the aforementioned polymers are determined by GPC (gel permeation chromatography).

The carboxylic acid polymers are formed from unsaturated monocarboxylic acids and unsaturated dicarboxylic acids. Typical unsaturated monocarboxylic acid monomers contain 3 to 6 carbon atoms and include acrylic acid, oligomeric acrylic acid, methacrylic acid, crotonic acid and vinyl acetic acid. Typical unsaturated dicarboxylic acids contain 4 to 8 carbon atoms and include the anhydrides thereof and are, for example, maleic acid, maleic anhydride, fumaric acid, glutaric acid, itaconic acid, itaconic anhydride, and cyclohexene dicarboxylic acid. In addition, water soluble salts of the aforementioned acids also can be used.

Particularly useful are “poly(meth)acrylic acids” having a number average molecular weight of about 1,000 to 1,500,000 preferably 3,000 to 250,000 and more preferably, 20,000 to 200,000. As used herein, the term “poly(meth)acrylic acid” is defined as polymers of acrylic acid, polymers of methacrylic acid or copolymers of acrylic acid and methacrylic acid. Blends of varying number average molecular weight poly(meth)acrylic acids are particularly preferred. In these blends or mixtures of poly(meth)acrylic acids, a lower number average molecular weight poly(meth)acrylic acid having a number average molecular weight of 1,000 to 100,000 and preferably, 4,000 to 40,000 is used in combination with a higher number average molecular weight poly(meth)acrylic acid having a number average molecular weight of 150,000 to 1,500,000, preferably, 200,000 to 300,000. Typically, the weight percent ratio of the lower number average molecular weight poly(meth)acrylic acid to the higher number average molecular weight poly(meth)acrylic acid is about 10:1 to 1:10, preferably 5:1 to 1:5, and more preferably, 3:1 to 2:3. A preferred blend comprises a poly(meth)acrylic acid having a number average molecular weight of about 20,000 and a poly(meth)acrylic acid having a number average molecular weight of about 200,000 in a 2:1 weight ratio.

In addition, carboxylic acid containing copolymers and terpolymers can be used in which the carboxylic acid component comprises 5-75% by weight of the polymer. Typical of such polymer are polymers of (meth)acrylic acid and acrylamide or methacrylamide; polymers of (meth)acrylic acid and styrene and other vinyl aromatic monomers; polymers of alkyl(meth)acrylates (esters of acrylic or methacrylic acid) and a mono or dicarboxylic acid, such as, acrylic or methacrylic acid or itaconic acid; polymers of substituted vinyl aromatic monomers having substituents, such as, halogen (i.e., chlorine, fluorine, bromine), nitro, cyano, alkoxy, haloalkyl, carboxy, amino, amino alkyl and a unsaturated mono or dicarboxylic acid and an alkyl(meth)acrylate; polymers of monethylenically unsaturated monomers containing a nitrogen ring, such as, vinyl pyridine, alkyl vinyl pyridine, vinyl butyrolactam, vinyl caprolactam, and an unsaturated mono or dicarboxylic acid; polymers of olefins, such as, propylene, isobutylene, or long chain alkyl olefins having 10 to 20 carbon atoms and an unsaturated mono or dicarboxylic acid; polymers of vinyl alcohol esters, such as, vinyl acetate and vinyl stearate or vinyl halides, such as, vinyl fluoride, vinyl chloride, vinylidene fluoride or vinyl nitriles, such as, acrylonitrile and methacrylonitrile and an unsaturated mono or dicarboxylic acid; polymers of alkyl(meth)acrylates having 1-24 carbon atoms in the alkyl group and an unsaturated monocarboxylic acid, such as, acrylic acid or methacrylic acid. These are only a few examples of the variety of polymers that can be used in the novel polishing composition of this invention. Also, it is possible to use polymers that are biodegradeable, photodegradeable or degradeable by other means. An example of such a composition that is biodegradeable is a polyacrylic acid polymer containing segments of poly(acrylate comethyl 2-cyanoacrylate).

Advantageously, the polishing composition contains 0.2 to 6 weight percent abrasive to facilitate silica removal. Within this range, it is desirable to have the abrasive present in an amount of greater than or equal to 0.5 weight percent. Also, desirable within this range is an amount of less than or equal to 2.5 weight percent.

The abrasive has an average particle size between 50 to 200 nanometers (nm). For purposes of this specification, particle size refers to the average particle size of the abrasive. More preferably, it is desirable to use an abrasive having an average particle size between 80 to 150 nm. Decreasing the size of the abrasive to less than or equal to 80 nm, tends to improve the planarization of the polishing composition, but, it also tends to decrease the removal rate.

Example abrasives include inorganic oxides, inorganic hydroxides, metal borides, metal carbides, metal nitrides, polymer particles and mixtures comprising at least one of the foregoing. Suitable inorganic oxides include, for example, silica (SiO₂), alumina (Al₂O₃), zirconia (ZrO₂), ceria (CeO₂), manganese oxide (MnO₂), or combinations comprising at least one of the foregoing oxides. Modified forms of these inorganic oxides, such as, polymer-coated inorganic oxide particles and inorganic coated particles may also be utilized if desired. Suitable metal carbides, boride and nitrides include, for example, silicon carbide, silicon nitride, silicon carbonitride (SiCN), boron carbide, tungsten carbide, zirconium carbide, aluminum boride, tantalum carbide, titanium carbide, or combinations comprising at least one of the foregoing metal carbides, boride and nitrides. Diamond may also be utilized as an abrasive if desired. Alternative abrasives also include polymeric particles and coated polymeric particles. The preferred abrasive is ceria.

The compounds provide efficacy over a broad pH range in solutions containing a balance of water. This solution's useful pH range extends from at least 4 to 9. In addition, the solution advantageously relies upon a balance of deionized water to limit incidental impurities. The pH of the polishing fluid of this invention is preferably from 4.5 to 8, more preferably a pH of 5.5 to 7.5. The acids used to adjust the pH of the composition of this invention are, for example, nitric acid, sulfuric acid, hydrochloric acid, phosphoric acid and the like. Exemplary bases used to adjust the pH of the composition of this invention are, for example, ammonium hydroxide and potassium hydroxide.

Optionally, the composition of the present invention may comprise 0 to 5 weight percent cationic compound. Preferably, the composition optionally comprises 0.05 to 1.5 weight percent cationic compound. The cationic compound of the present invention may advantageously promote planarization, regulate wafer-clearing time and serve to suppress oxide removal. Preferred cationic compounds include, alkyl amines, aryl amines, quaternary ammonium compounds and alcohol amines. Exemplary cationic compounds include, methylamine, ethylamine, dimethylamine, diethylamine, trimethylamine, triethylamine, aniline, tetramethylammoniumhydroxide, tetraethylammoniumhydroxide, ethanolamine and propanolamine.

Accordingly, the present invention provides a composition useful for polishing silica and silicon nitride on a semiconductor wafer for shallow trench isolation processes. The composition advantageously comprises zwitterionic compounds for improved selectivity. In particular, the present invention provides an aqueous composition useful for polishing silica and silicon nitride on a semiconductor wafer comprising 0.01 to 5 zwitterionic compound, 0.01 to 5 carboxylic acid polymer, 0.02 to 6 abrasive, 0 to 5 cationic compound and balance water. The composition exhibits particularly improved selectivity at a pH range of 4 to 9.

### EXAMPLES

In the Examples, numerals represent examples of the invention and letters represent comparative examples. All example solutions contained, by weight percent, 1.8 ceria and 0.18 polyacrylic acid.

### Example 1

This experiment measured the selectivity of silica relative to silicon nitride on a semiconductor wafer. In particular, the effect of betaine (N,N,N-trimethylammonioacetate) on selectivity of silica relative to silicon nitride was tested. An IPEC 472 DE 200 mm polishing machine using an IC1000™ polyurethane polishing pad (Rohm and Haas Electronic Materials CMP Technologies) under downforce conditions of about 5 psi and a polishing solution flow rate of 150 cc/min, a platen speed of 52 RPM and a carrier speed of 50 RPM planarized the samples. The polishing solutions had a pH of 6.5 adjusted with nitric acid or ammonium hydroxide. All solutions contained deionized water.

TABLE 1

| | Abrasive | PAA | Betaine | Ethanolamine | TEOS | SiN | |
|---|---|---|---|---|---|---|---|
| Test | (wt. %) | (wt. %) | (wt. %) | (wt. %) | (Å/min) | (Å/min) | Selectivity |
| A | 1.8 | 0.18 | — | — | 3200 | 80 | 40 |
| 1 | 1.8 | 0.18 | 0.5 | — | 3000 | 45 | 66 |
| B | 1.8 | 0.18 | — | 0.3 | 1850 | 130 | 14 |
| 3 | 1.8 | 0.18 | 0.5 | 0.3 | 2500 | 130 | 19 |

As illustrated in Table 1 above, the addition of the zwitterionic compound improved the selectivity of the composition. In particular, the addition of the N,N,N-trimethylammonioacetate improved the selectivity of the composition of Test 1 for the TEOS relative to the silicon nitride from 40 (Test A) to 66. The addition of the N,N,N-trimethylammonioacetate suppressed the silicon nitride from 80 Å/min to 45 Å/min, in Test A and Test 1, respectively. The addition of ethanolamine suppressed the TEOS removal rate from 3200 Å/min to 1850 Å/min, in Test A and Test B, respectively.

Accordingly, the present invention provides a composition useful for polishing silica and silicon nitride on a semiconductor wafer for shallow trench isolation processes. The composition advantageously comprises zwitterionic compounds for improved selectivity and controllability during the polishing process. In particular, the present invention provides an aqueous composition useful for polishing silica and silicon nitride on a semiconductor wafer comprising a zwitterionic compound, carboxylic acid polymer, abrasive and balance water. Optionally, the compound of the present invention may contain a cationic compound to promote planarization, regulate wafer-clearing time and silica removal.

1. An aqueous composition useful for polishing silica and silicon nitride on a semiconductor wafer comprising by weight percent 0.01 to 5 zwitterionic compound, 0.01 to 5 carboxylic acid polymer, 0.02 to 6 abrasive, 0 to 5 cationic compound and balance water, the zwitterionic compound having the following structure: 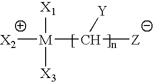
wherein n is an integer, Y comprises hydrogen or an alkyl group, Z comprises carboxyl, sulfate or oxygen, M comprises nitrogen, phosphorus or a sulfur atom, and X₁, X₂ and X₃ independently comprise substituents selected from the group comprising, hydrogen, an alkyl group and an aryl group.

2. The composition of claim 1 wherein the zwitterionic compound has the following structure:

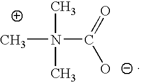

3. The composition of claim 1 wherein the cationic compound is selected from the group comprising: alkyl amines, aryl amines, quaternary ammonium compounds and alcohol amines.

4. The composition of claim 1 wherein the abrasive is ceria.

5. The composition of claim 4 wherein the ceria has an average particle size of between 50-200 nm.

6. The composition of claim 1 wherein the aqueous composition has a pH of 4 to 9.

7. An aqueous composition useful for polishing silica and silicon nitride on a semiconductor wafer comprising by weight percent 0.01 to 5 N,N,N-trimethylammonioacetate, 0.01 to 5 polyacrylic acid polymer, 0.02 to 6 ceria, 0 to 5 cationic compound and balance water, wherein the aqueous composition has a pH of 4 to 9.

8. A method for polishing silica and silicon nitride on a semiconductor wafer comprising:
contacting the silica and silicon nitride on the wafer with a polishing composition, the polishing composition comprising by weight percent 0.01 to 5 zwitterionic compound, 0.01 to 5 carboxylic acid polymer, 0.02 to 6 abrasive, 0 to 5 cationic compound and balance water;
polishing the silica and silicon nitride with a polishing pad; and
wherein the zwitterionic compound has the following structure: 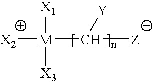
in which n is an integer, Y comprises hydrogen or an alkyl group, Z comprises carboxyl, sulfate or oxygen, M comprises nitrogen, phosphorus or a sulfur atom, and X₁, X₂ and X₃ independently comprise substituents selected from the group comprising, hydrogen, an alkyl group and an aryl group.

9. The method of claim 8 wherein the zwitterionic compound has the following structure:

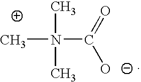

10. The method of claim 8 wherein the cationic compound is selected from the group comprising: alkyl amines, aryl amines, quaternary ammonium compounds and alcohol amines.
